(19) United States
(12) Patent Application Publication
(10) Pub. No.: US 2025/0316300 A1
(43) Pub. Date: Oct. 9, 2025

(54) CLOCK GATING OF FREE INDEX FLOP ARRAYS

(71) Applicant: NVIDIA Corporation, Santa Clara, CA (US)

(72) Inventors: Anil Mugu, Bangalore (IN); Shanthan Chakilam, Bangalore (IN); Lakshita, Bangalore (IN); Raavikrindi Rangateja, Bangalore (IN); Ronit Vijaybhai Patel, Bangalore (IN)

(21) Appl. No.: 18/667,112

(22) Filed: May 17, 2024

(30) Foreign Application Priority Data
Apr. 5, 2024 (IN) 202411028223

(51) Int. Cl. G11C 7/22; G11C 7/10

(52) U.S. Cl. CPC G11C 7/222; G11C 7/1006; G11C 7/1069

(57) ABSTRACT

A system is described to include a first storage element having a plurality of data storage locations, a second storage element having an array of bits indicating an availability for a corresponding data storage location in the plurality of data storage locations, and a control circuit. The control circuit may include at least a first switching element coupled to a first set of bits in the array of bits, the at least a first switching element selectively enables the first set of bits to be read or written in response to being activated by a first clock gating signal as well as at least a second switching element coupled to a second set of bits in the array of bits, the at least a second switching element selectively enables the second set of bits to be read or written in response to being activated by a second clock gating signal.

### FIELD OF THE DISCLOSURE

The present disclosure is generally directed toward computer memory devices and, in particular, toward saving power associated with managing computer memory devices.

### BACKGROUND

Power saving is one of the most important aspects of semiconductor design. One way to save power across the semiconductor is to optimize the power consumed by commonly replicated/used logic. Free index handling is one such logic, which is widely used in different blocks. Free index logic is used to track available addresses (entries) in storage elements like multi-threaded First-In-First-Out (FIFO) buffers, response buffers, and trackers. Traditional free index logic uses a flop per entry of the storage to track availability. Such an architecture results in the flop array being as deep as the storage itself.

### BRIEF SUMMARY

Clock gating is a power saving technique where a clock is gated whenever logic is not in use. Most existing free index flop array designs utilize a single clock gating for the entire free index flop array. Controlling the free index flop array in this manner leads to the entire free index flop array being activated for every access causing unnecessary power utilization.

Embodiments of the present disclosure aim to improve power consumption for semiconductor devices and chips. Power consumption can be improved by optimizing free index logic used to track available addresses/entries in storage elements like multi-threaded FIFOs, response buffers, and trackers. Whereas traditional free index logic utilize a single clock gating signal (inclusive of clock gating signal and a clock gating cell) for an entire free index flop array, embodiments of the present disclosure divide the free index flop array into two or more subgroups. Each subgroup of the free index flop array is controlled by separate clock gating signals, thereby enabling each subgroup to be awaken only when needed. For every memory access only the intended subgroups are woken up and rest of the subgroups are kept off. As can be appreciated, the granularity of the groups can vary and may be decided based on power requirements and permissible area allowances or power constraints placed on the semiconductor device.

Example aspects of the present disclosure provide a system is provided, including: a first storage element including a plurality of data storage locations; a second storage element including an array of bits indicating an availability for a corresponding data storage location in the plurality of data storage locations; and a control circuit including: at least a first switching element coupled to a first set of bits in the array of bits, where the at least a first switching element selectively enables the first set of bits to be read or written in response to being activated by a first clock gating signal; and at least a second switching element coupled to a second set of bits in the array of bits, where the at least a second switching element selectively enables the second set of bits to be read or written in response to being activated by a second clock gating signal.

In some aspects, the at least a first switching element and the at least a second switching element are connected to a common ungated clock signal.

In some aspects, a number of bits in the first set of bits is equal to a number of bits in the second set of bits.

In some aspects, a number of bits in the first set of bits is different from a number of bits in the second set of bits.

In some aspects, the number of bits in the first set of bits is less than the number of bits in the second set of bits.

In some aspects, the at least a first switching element includes a first digital logic element and wherein the at least a second switching element includes a second digital logic element.

In some aspects, the first storage element includes multiple storage sub-elements and the second storage element includes multiple storage sub-elements.

In some aspects, the first set of bits is activated with the first clock gating signal and enabled to be read to identify a state of a first set of data storage locations in the first storage element.

In some aspects, the first set of bits is activated with the first clock gating signal and enabled to be written to update state of a first set of data storage locations in the first storage element.

In some aspects, one or more writes are performed to a free index flop array at a given time to update a status of data storage locations.

In some aspects, the second set of bits is activated with the second clock gating signal and enabled to be read to identify a state of a second set of data storage locations in the first storage element and wherein the second clock gating signal operates independent of the first clock gating signal.

In some aspects, the first storage element includes a readable and writable memory device.

In some aspects, the first storage element includes a Random Access Memory (RAM) device.

In some aspects, the array of bits is provided as part of a flop array or flop vector or array of flops.

In some aspects, the first set of bits are activated to be read with the first clock gating signal when data from a corresponding first set of data storage locations in the plurality of data storage locations is to have data read therefrom and the second set of bits are activated to be read with the second clock gating signal when data from a corresponding second set of data storage locations in the plurality of data storage locations is to have data read therefrom.

In some aspects, the first set of bits are activated to be written with the first clock gating signal when data to a corresponding first set of data storage locations in the plurality of data storage locations is written and the second set of bits are activated to be written with the second clock gating signal when data to a corresponding second set of data storage locations in the plurality of data storage locations to be written.

In another illustrative example, a control circuit is provided to selectively activate an array of bits, where the array of bits indicate an availability for data storage locations in a storage element. According to at least some embodiments, the control circuit includes: a first switching element coupled to a first set of bits in the array of bits, where the first switching element selectively enables the first set of bits to be read or written in response to activation by a first clock gating signal; and a second switching element coupled to a second set of bits in the array of bits, where the second switching element selectively enables the second set of bits to be read or written in response to activation by a second clock gating signal that is different from the first clock gating signal.

In some aspects, the first set of bits are activated to be read or written with the first clock gating signal when data from a corresponding first set of data storage locations is to have data read therefrom or to be written, where the second set of bits are activated to be read or written with the second clock gating signal when data from a corresponding second set of data storage locations is to have data read therefrom or written to, where the first set of bits is non-overlapping with the second set of bits, and where the first set of data storage locations is non-overlapping with the second set of data storage locations.

In some aspects, the first set of bits are deactivated in an absence of the first clock gating signal when data from the corresponding first set of data storage locations is not to have data read therefrom or no data to be written and where the second set of bits are deactivated in an absence of the second clock gating signal when data from the corresponding second set of data storage locations is not to have data read therefrom or no data to be written.

In some aspects, a number of bits in the array of bits is equal to a number of data storage locations in the storage element.

In some aspects, the array of bits of bits is divided into a number of subgroups and each subgroup in the number of subgroups provided with a corresponding switching element to manage a clock gate provided to the corresponding subgroup.

In another example, a semiconductor device is described to include: an array of bits indicating an availability for a corresponding data storage location in a data storage element, where the array of bits is divided into a number of subgroups; and a control circuit to manage clock gating for the array of bits, where the control circuit provides a separate clock gating signal to each subgroup of bits in the array of bits to independently control when each subgroup is activated.

In some aspects, each subgroup, in an absence of receiving a clock-enable (CE) signal from the control circuit, is deactivated and requires less power as compared to when the subgroup is activated with a CE signal.

In some aspects, the control circuit includes a number of switching elements equal to the number of subgroups and each switching element is used to selectively control whether a CE signal is provided to a corresponding subgroup.

Additional features and advantages are described herein and will be apparent from the following description and the figures.

### BRIEF DESCRIPTION OF THE SEVERAL VIEWS OF THE DRAWINGS

The present disclosure is described in conjunction with the appended figures, which are not necessarily drawn to scale:

FIG. 1 is a block diagram depicting an illustrative system in accordance with at least some embodiments of the present disclosure;

FIG. 2A is a block diagram depicting a first example configuration of storage elements in accordance with at least some embodiments of the present disclosure;

FIG. 2B is a block diagram depicting a second example configuration of storage elements in accordance with at least some embodiments of the present disclosure;

FIG. 2C is a block diagram depicting a third example configuration of storage elements in accordance with at least some embodiments of the present disclosure;

FIG. 2D is a block diagram depicting a fourth example configuration of storage elements in accordance with at least some embodiments of the present disclosure;

FIG. 3 is a block diagram illustrating a traditional control circuit for a free index flop array; and

FIG. 4 is a block diagram illustrating a control circuit for a free index flop array in accordance with at least some embodiments of the present disclosure.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

It will be appreciated from the following description, and for reasons of computational efficiency, that the components of the system can be arranged at any appropriate location within a distributed network of components without impacting the operation of the system.

Furthermore, it should be appreciated that the various links connecting the elements can be wired, traces, or wireless links, or any appropriate combination thereof, or any other appropriate known or later developed element(s) that is capable of supplying and/or communicating data to and from the connected elements. Transmission media used as links, for example, can be any appropriate carrier for electrical signals, including coaxial cables, copper wire and fiber optics, electrical traces on a printed circuit board (PCB), or the like.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “automatic” and variations thereof, as used herein, refers to any appropriate process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The terms “determine,” “calculate,” “compute,” and variations thereof, as used herein, are used interchangeably, and include any appropriate type of methodology, process, operation, or technique.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

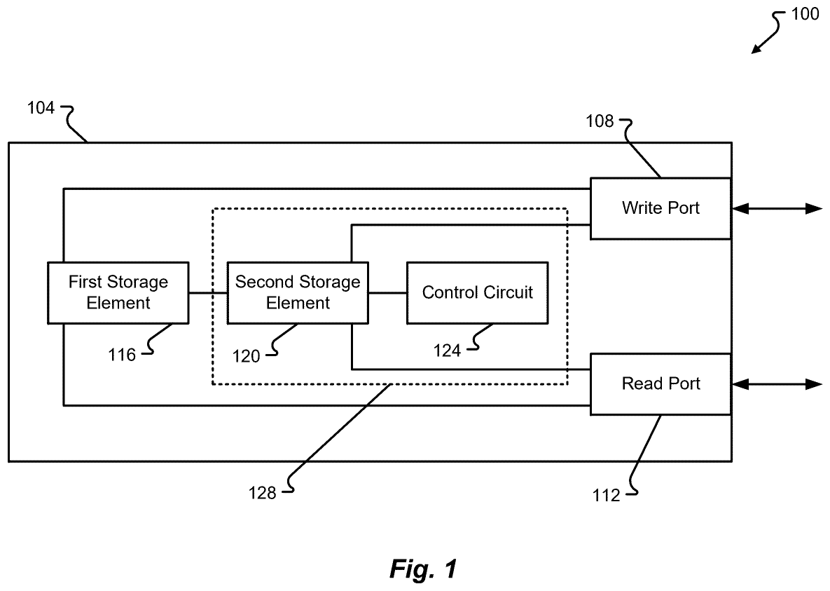

Referring now to FIGS. 1-4, various systems and circuits for controlling a free index flop array in a power efficient manner will be described in accordance with at least some embodiments of the present disclosure. According to at least some embodiments of the present disclosure, an index-based Clock Gating (CG) approach to controlling a free index flop array is proposed. In index-based CG, some or all of the free index flop array may be divided into two, three, four, or more smaller subgroups. Each subgroup may be independently managed with separate CG signals. For instance, each subgroup may be woken up only when an entry in the subgroup is to be accessed (e.g., for a read or write operation). The size/number/granularity of the subgroups may be configurable and, in some embodiments, may be defined based on permissible area allowances or power constraints placed on the semiconductor device.

As illustrated in FIG. 1, a system 100 may include a computing device 104 having a write port 108 and read port 112. The computing device 104 may correspond to any suitable type of device used for conducting processing computational tasks, storing data, communicating data, or the like. Illustratively, and without limitation, the computing device 104 may correspond to a network endpoint, server, switch, or the like. Alternatively, the computing device 104 may be provided as part of a larger computing system. For instance, the computing device 104 may be provided as a processing unit (e.g., Central Processing Unit (CPU), Graphics Processing Unit (GPU), Data Processing Unit (DPU), Application-Specific Integrated Circuit (ASIC), microprocessor, or other circuit(s) capable of performing computations, as well as memory and storage resources to run software applications, handle data processing, and perform specific tasks as required for a larger computing system.

Additionally, while the write port 108 and read port 112 are illustrated as separate components, it should be appreciated that a single port can be provided to support both read and write functionality. In other words, a computing device 104 may include a single port that operates as both a write port 108 and a read port 112. The write port 108 and read port 112 may correspond to a logical and/or physical interface between components of the computing device 104 and other devices.

The computing device 104 further includes a first storage element 116, a second storage element 120, and a control circuit 124. Some or all of the components of the computing device 104 may be provided as part of a semiconductor device 128 (e.g., on a common piece of silicon). The illustrated example shows the second storage element 120 and control circuit 124 as being provided in the semiconductor device 128. It should be appreciated that the first storage element 116 may also be included in the semiconductor device 128. In another possible configuration, the control circuit 124 may correspond to the only portion of the computing device provided in the semiconductor device 128. In another possible configuration, each component of the computing device 104 may be provided on separate semiconductor devices.

The first storage element 116 may correspond to any suitable type of computer memory device. In some embodiments, the first storage element 116 may include a plurality of data storage locations. The first storage element 116 may, for example, include a computer memory device such as Random Access Memory (RAM), Dynamic RAM (DRAM), flash memory, Non-Volatile RAM (NVRAM), Ternary Content-Addressable Memory (TCAM), Static RAM (SRAM), and/or memory elements of other formats.

The second storage element 120 may be used to track memory availability associated with the first storage element 116. More specifically, the second storage element 120 may include an array of bits indicating an availability for a corresponding data storage location in the plurality of data storage locations provided in the first storage element 116. In some embodiments, the second storage element 120 may be used to support free index logic that it used to track available addresses/entries in storage elements like multi-threaded FIFOs, response buffers, and trackers. Non-limiting examples of a second storage element 120 include a flop array, a flop vector, and an array of flops.

The control circuit 124 may be coupled with the second storage element 120 and may be configured to manage various aspects of the second storage element 120. For instance, and in accordance with at least some embodiments of the present disclosure, the control circuit 124 may be configured to manage clock gating for the array of bits provided in the second storage element 120. More specifically, the control circuit 124 may provide a separate clock gating signal to each subgroup of bits in the array of bits to independently control when each subgroup is activated. In this way, the control circuit 124 avoids unnecessarily activating bits in the second storage element 120, thereby conserving power associated with providing free index logic. While illustrated as a single component, it should be appreciated that the control circuit 124 may include one or multiple circuits to provide the functionality described herein.

In some embodiments, the control circuit 124 may include a first switching element coupled to a first set of bits in the array of bits in the second storage element 120. The first switching element may selectively enable the first set of bits to be read or written in response to being activated by a first clock gating signal. The control circuit 124 may further include a second switching element coupled to a second set of bits in the array of bits in the second storage element 120. The second switching element may selectively enable the second set of bits to be read or written in response to being activated by a second clock gating signal. The first clock gating signal may be separate from the second clock gating signal.

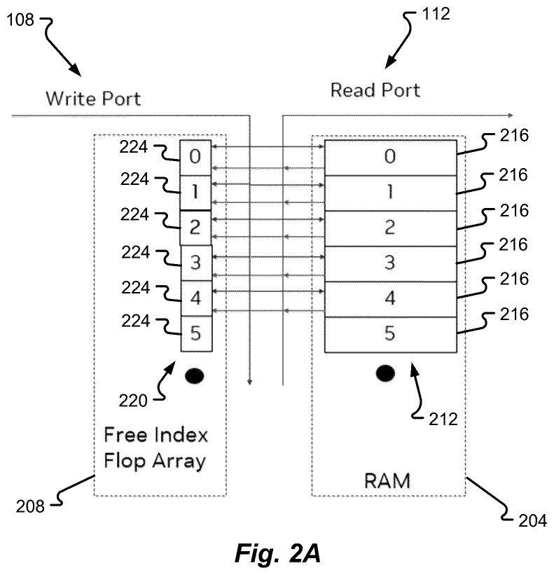

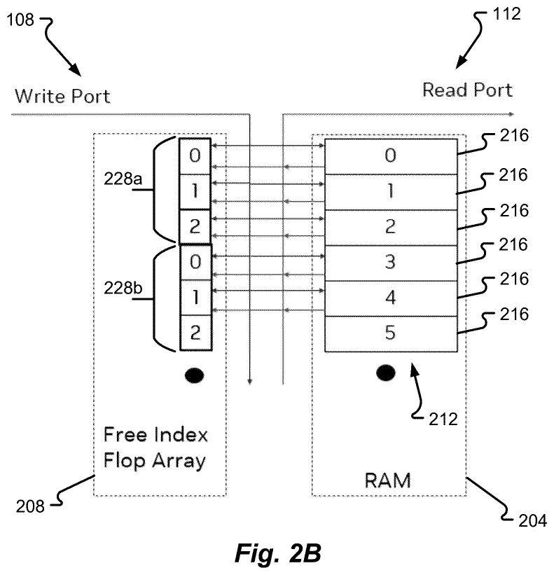

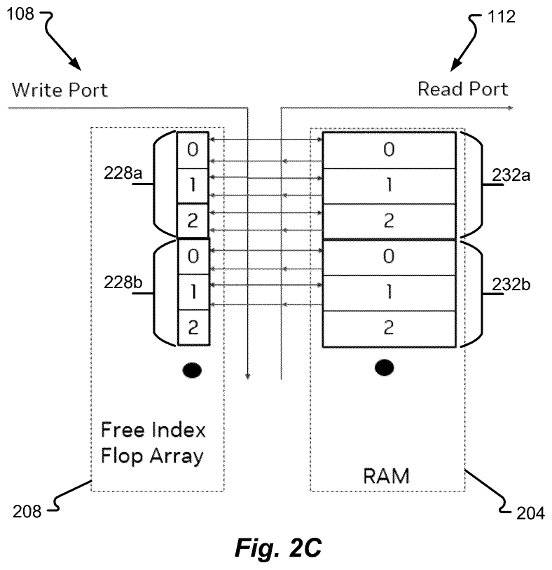

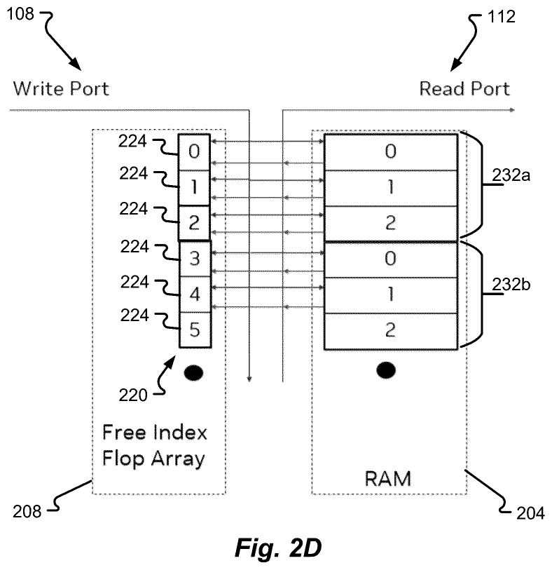

With reference now to FIGS. 2A thru 2D, various possible configurations of the first storage element 116 and second storage element 120 will be described in accordance with at least some embodiments of the present disclosure. A first example configuration is shown in FIG. 2A where the first storage element 116 is depicted as RAM 204 having a plurality of data storage locations 212. Each data storage location 216 in the plurality of data storage locations 212 may be configured to store data (e.g., 0 to N bits in size, where N is an integer number greater than or equal to one) using any suitable type of data storage technology (e.g., electronic media, magnetic media, optical media, quantum media, or the like). FIG. 2A also illustrates the second storage element 120 as a free index flop array 208 having an array of bits 220. Each bit 224 in the array of bits 220 may indicate an availability (e.g., positively or negatively) for corresponding data storage locations 216 in the plurality of data storage locations 212.

As will be described in further detail herein, the bits 224 in the array of bits 220 may be divided into one or more subgroups that are independently controlled by the control circuit 124. More specifically, the array of bits 220 may be divided into multiple subgroups and the control circuit 124 may utilize a different clock gating signal to independently control activation/deactivation of each subgroup of bits in the array of bits 220. In some embodiments, each clock gating signal may be provided to the subgroup of bits by a different switching element, such as a clock gate or similar type of digital logic element.

In the illustrated example, the number of data storage locations 216 in the plurality of data storage locations 212 is equal to the number of bits 224 in the array of bits 220, meaning that there is a 1:1 ratio of data storage locations 216 to bits 224. It should be appreciated, however, that such a configuration is not required. Additionally, while the number of data storage locations 216 and bits 224 is illustrated to be a particular number (e.g., six), it should be appreciated that the illustrated number of data storage locations 216 and bits 224 is provided as an example and should not be construed as limiting. For instance, the number of data storage locations 216 in the plurality of data storage locations 212 may be any number greater than one. Likewise, the number of bits 224 in the array of bits 220 may be any number greater than one.

FIG. 2A illustrates a configuration where the first storage element 116 (e.g., RAM 204) comprises a single storage element (e.g., a single computer memory device) and where the second storage element 120 (e.g., free index flop array 208) comprises a single storage element (e.g., a single computer memory device). In accordance with at least some embodiments of the present disclosure, the first storage element 116 may include multiple storage sub-elements and/or the second storage element 120 may include multiple storage sub-elements.

FIG. 2B illustrates a configuration where the second storage element 120 (e.g., free index flop array 208) comprises multiple storage sub-elements. More specifically, the free index flop array 208 is shown to include at least a first storage sub-element 228a and at least a second storage sub-element 228b. The first storage sub-element 228a of the second storage element 120 may include a first array of bits whereas the second storage sub-element 228b may include a second array of bits. The combination of bits 224 in both storage sub-elements 228a, 228b of the second storage element 120 may be considered the array of bits 220.

The first storage sub-element 228a of the second storage element 120 may include bits 224 used to track availability of a first set of data storage locations 216 in the plurality of data storage locations 212 while the second storage sub-element 228b of the second storage element 120 may include bits 224 used to track availability of a second set of data storage locations 216 in the plurality of data storage locations 212. While the number of bits 224 in the first storage sub-element 228a and second storage sub-element 228b of the second storage element 120 are illustrated as being equal, such a configuration is not required. For instance, the first storage sub-element 228a may have greater or fewer bits 224 as compared to the second storage sub-element 228b of the second storage element 120 without departing from the scope of the present disclosure. Additionally, the type of memory device used for the first storage sub-element 228a of the second storage element 120 may be the same as the type of memory device used for the second storage sub-element 228b of the second storage element 120. Alternatively, the type of memory device used for the first storage sub-element 228a of the second storage element 120 may be different from the type of memory device used for the second storage sub-element 228b of the second storage element 120. Furthermore, it should be appreciated that the second storage element 120 may include two, three, four, or more separate sub-elements without departing from the scope of the present disclosure.

FIG. 2C illustrates a configuration where the first storage element 116 (e.g., RAM 204) and the second storage element 120 (e.g., free index flop array 208) both comprise multiple storage sub-elements. More specifically, the configuration of the second storage element 120 is similar to the configuration illustrated in FIG. 2B. However, the RAM 204 of FIG. 2C is shown to include at least a first storage sub-element 232a and at least a second storage sub-element 232b. The first storage sub-element 232a of the first storage element 116 may include a first set of data storge locations 216 whereas the second storage sub-element 232b of the first storage element 116 may include a second set of data storage locations 216. The combination of data storage locations 216 in both storage sub-elements 232a, 232b of the first storage element 116 may be considered the plurality of data storage locations 212.

While FIG. 2C illustrates the first storage sub-element 228a of the second storage element 120 having the same size as the first storage sub-element 232a of the first storage element 116 and the second storage sub-element 228b of the second storage element 120 having the same size as the second storage sub-element 232b of the first storage element 116, it should be appreciated that such a configuration is not required. Specifically, and without limitation, bits 224 in the first storage sub-element 228a may be used to track availability for data storage locations 216 in one, two, three, four, or more different storage sub-elements of the first storage element 116.

The type of memory device used for the first storage sub-element 232a of the first storage element 116 may be the same as the type of memory device used for the second storage sub-element 232b of the first storage element 116. Alternatively, the type of memory device used for the first storage sub-element 232a of the first storage element 116 may be different from the type of memory device used for the second storage sub-element 232b of the first storage element 116. Furthermore, it should be appreciated that the first storage element 116 may include two, three, four, or more separate sub-elements without departing from the scope of the present disclosure.

FIG. 2D illustrates another possible configuration of the first storage element 116 and second storage element 120. More specifically, FIG. 2D illustrates a configuration where the first storage element 116 (e.g., RAM 204) comprises multiple storage sub-elements but the second storage element 120 (e.g., free index flop array 208) comprises a single storage element. More specifically, the configuration of the first storage element 116 is similar to the configuration illustrated in FIG. 2C whereas the configuration of the second storage element 120 is similar to the configuration illustrated in FIG. 2A.

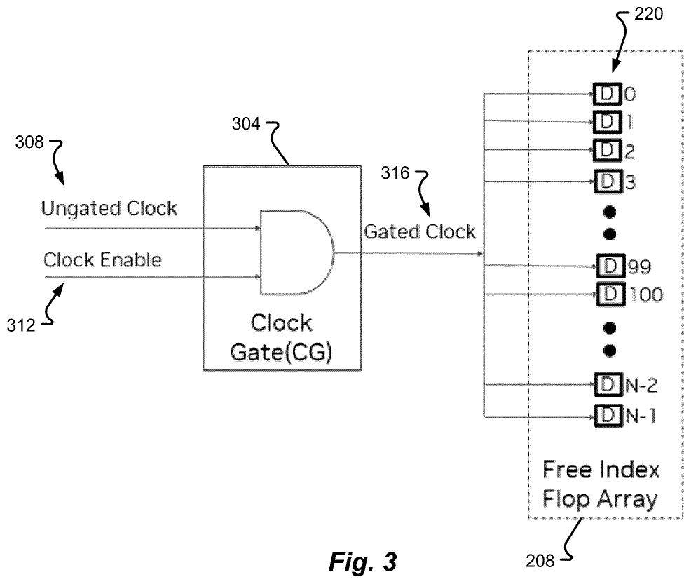

Referring now to FIG. 3, components of a control circuit 124 used to manage a free index flop array 208 are illustrated. The configuration of FIG. 3 depicts a traditional configuration of a control circuit 124 in which a single clock gating signal 316 is used to control every bit 224 in the array of bits 220. Specifically, the control circuit 124 may include a switching element 304, such as a clock gate (CG). The switching element 304 may produce the single clock gating signal 316 based on one or more inputs provided thereto. For instance, the switching element 304 may receive an ungated clock signal 308 and a clock enable (CE) signal 312. The ungated clock signal 308 may include any suitable type of clock signal, such as a clock signal generated from a free running clock or a derived clock. The switching element 304 may generate the single clock gating signal 316 based on a logical combination of the ungated clock signal 308 and the CE signal 312.

As discussed above, controlling the free index flop array 208 in the manner depicted in FIG. 3 may result inefficient power consumption. Specifically, any time one bit 224 in the array of bits 220 is to be activated (e.g., to support a read or write operation), every bit 224 in the array of bits 220 is activated.

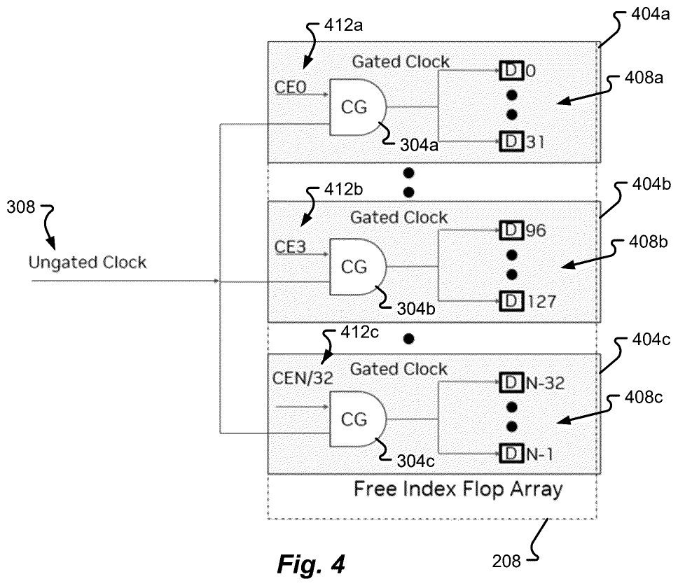

FIG. 4 illustrates an improved configuration of a control circuit 124 in accordance with at least some embodiments of the present disclosure. The control circuit 124 may be provided with two or more switching elements where each switching element is used to control a discrete subgroup of bits 224 in the array of bits 220. The illustrated configuration is shown to include a first switching element 304a used to control a first set of bits 408a in the array of bits 220, a second switching element 304b used to control a second set of bits 408b in the array of bits 220, and a third switching element 304c used to control a third set of bits 408c in the array of bits 220. While three switching elements 304a, 304b, 304c are shown in FIG. 4, it should be appreciated that a control circuit 124 according to embodiments of the present disclosure may be configured with two, three, four, or more switching elements. The illustrated details of three switching elements 304a, 304b, 304c is for purposes of supporting an understanding of the control circuit 124 and capabilities thereof.

The first switching element 304a and the first set of bits 408a may be considered part of a first control subgroup 404a. The first set of bits 408a belonging to the first control subgroup 404a may be controlled by a first clock gating signal generated by the first switching element 304a. The first switching element 304a may produce the first clock gating signal based on a first CE signal 412a and an ungated clock signal 308. In some embodiments, the first switching element 304a produces the first clock gating signal based on a logical combination of the first CE signal 412a and the ungated clock signal 308.

The second switching element 304b and the second set of bits 408b may be considered part of a second control subgroup 404b. The second set of bits 408b belonging to the second control subgroup 404b may be controlled by a second clock gating signal generated by the second switching element 304b. The second switching element 304b may produce the second clock gating signal based on a second CE signal 412b and the ungated clock signal 308. The ungated clock signal 308 may be the same ungated clock signal 308 provided to the first switching element 304a. In some embodiments, the second switching element 304b produces the second clock gating signal based on a logical combination of the second CE signal 412b and the ungated clock signal 308.

The third switching element 304c and the third set of bits 408c may be considered part of a third control subgroup 404c. The third set of bits 408c belonging to the third control subgroup 404c may be controlled by a third clock gating signal generated by the third switching element 304c. The third switching element 304c may produce the third clock gating signal based on a third CE signal 412c and the ungated clock signal 308. The ungated clock signal 308 may be the same ungated clock signal 308 provided to the first switching element 304a and second switching element 304b. In some embodiments, the third switching element 304c produces the third clock gating signal based on a logical combination of the third CE signal 412c and the ungated clock signal 308.

In accordance with at least some embodiments of the present disclosure, the set of bits in a control subgroup may be activated and/or deactivated based on the logic provided by the corresponding clock gating signal. In some embodiments, a set of bits may be activated with a clock gating signal and enabled to be written to update state of the corresponding set of data storage locations in the first storage element 116. For example, the first set of bits 408a may be activated with the first clock gating signal produced by the first switching element 304a to enable a write operation based on the combined logic of the ungated clock signal 308 and the first CE signal 412a. In some embodiments, one or more writes may be performed to a free index flop array 208 at a given time to update a status of corresponding data storage locations. Similarly, a set of bits may be activated with a clock gating signal and enabled to be read to identify a state of the corresponding set of data storage locations in the first storage element 116. For example, the first set of bits 408a may be activated with the first clock gating signal produced by the first switching element 304a to enable a read operation based on the combined logic of the ungated clock signal 308 and the first CE signal 412a.

In some embodiments, the clock gating signals produced by each switching element 304a, 304b, 304c may be operated independent of one another. The control circuit 124 may be configured to only activate the set of bits needed to support a read or write operation. Other bits not belonging to the set of bits involved in the read or write operation may remain deactivated, thereby conserving power associated with accessing the free index flop array 208. Said another way, the first set of bits 408a may be activated to be read or written with the first clock gating signal when data from a corresponding first set of data storage locations is to have data read therefrom or to be written. Similarly, the second set of bits 408b may be activated to be read or written with the second clock gating signal when data from a corresponding second set of data storage locations is to have data read therefrom or written to. The first set of bits 408a is non-overlapping with the second set of bits 408b and the corresponding first set of data storage locations is non-overlapping with the corresponding second set of data storage locations.

Furthermore, the first set of bits 408a may be deactivated in an absence of the first clock gating signal when data from the corresponding first set of data storage locations is not to have data read therefrom or no data to be written. Similarly, the second set of bits 408b may be deactivated in an absence of the second clock gating signal when data from the corresponding second set of data storage locations is not to have data read therefrom or no data to be written.

While FIG. 4 illustrates each control subgroup 404a, 404b, 404c as having the same number of bits, it should be appreciated that such a configuration is not required. For example, the number of bits 224 in any particular set of bits does not necessarily have to be the same as the number of bits 224 in the set of bits belonging to a different control subgroup. As a non-limiting example, the number of bits 224 in the first set of bits 408a may be different than (e.g., less than or greater than) the number of bits 224 in the second set of bits 408b or the number of bits 224 in the third set of bits 408c.

Each control subgroup 404a, 404b, 404c may be managed independently by the control circuit 124. In some embodiments, in an absence of the control circuit 124 providing a corresponding CE signal to a control subgroup, the set of bits belonging to the control subgroup may be deactivated and require less power as compared to when the set of bits are activated with a CE signal. As noted above, the control circuit 124 may include a number of switching elements equal to the number of control subgroups and each switching element is used to selectively control whether a CE signal is provided to the set of bits in the corresponding control subgroup.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A system, comprising:
a first storage element comprising a plurality of data storage locations;
a second storage element comprising an array of bits indicating an availability for a corresponding data storage location in the plurality of data storage locations; and
a control circuit comprising:
at least a first switching element coupled to a first set of bits in the array of bits, wherein the at least a first switching element selectively enables the first set of bits to be read or written in response to being activated by a first clock gating signal; and
at least a second switching element coupled to a second set of bits in the array of bits, wherein the at least a second switching element selectively enables the second set of bits to be read or written in response to being activated by a second clock gating signal.

2. The system of claim 1, wherein the at least a first switching element and the at least a second switching element are connected to a common ungated clock signal.

3. The system of claim 1, wherein a number of bits in the first set of bits is equal to a number of bits in the second set of bits.

4. The system of claim 1, wherein a number of bits in the first set of bits is different from a number of bits in the second set of bits.

5. The system of claim 4, wherein the number of bits in the first set of bits is less than the number of bits in the second set of bits.

6. The system of claim 1, wherein the at least a first switching element comprises a first digital logic element and wherein the at least a second switching element comprises a second digital logic element.

7. The system of claim 1, wherein the first storage element comprises multiple storage sub-elements and wherein the second storage element comprises multiple storage sub-elements.

8. The system of claim 1, wherein the first set of bits is activated with the first clock gating signal and enabled to be read to identify a state of a first set of data storage locations in the first storage element.

9. The system of claim 8, wherein the first set of bits is activated with the first clock gating signal and enabled to be written to update state of a first set of data storage locations in the first storage element.

10. The system of claim 9, wherein one or more writes are performed to a free index flop array at a given time to update a status of data storage locations.

11. The system of claim 8, wherein the second set of bits is activated with the second clock gating signal and enabled to be read to identify a state of a second set of data storage locations in the first storage element and wherein the second clock gating signal operates independent of the first clock gating signal.

12. The system of claim 1, wherein the first storage element comprises a readable and writable memory device.

13. The system of claim 12, wherein the first storage element comprises a Random Access Memory (RAM) device.

14. The system of claim 1, wherein the array of bits is provided as part of a flop array or flop vector or array of flops.

15. The system of claim 1, wherein the first set of bits are activated to be read with the first clock gating signal when data from a corresponding first set of data storage locations in the plurality of data storage locations is to have data read therefrom and wherein the second set of bits are activated to be read with the second clock gating signal when data from a corresponding second set of data storage locations in the plurality of data storage locations is to have data read therefrom.

16. The system of claim 1, wherein the first set of bits are activated to be written with the first clock gating signal when data to a corresponding first set of data storage locations in the plurality of data storage locations is written and wherein the second set of bits are activated to be written with the second clock gating signal when data to a corresponding second set of data storage locations in the plurality of data storage locations to be written.

17. A control circuit to selectively activate an array of bits, wherein the array of bits indicate an availability for data storage locations in a storage element, the control circuit comprising:
a first switching element coupled to a first set of bits in the array of bits, wherein the first switching element selectively enables the first set of bits to be read or written in response to activation by a first clock gating signal; and
a second switching element coupled to a second set of bits in the array of bits, wherein the second switching element selectively enables the second set of bits to be read or written in response to activation by a second clock gating signal that is different from the first clock gating signal.

18. The control circuit of claim 17, wherein the first set of bits are activated to be read or written with the first clock gating signal when data from a corresponding first set of data storage locations is to have data read therefrom or to be written, wherein the second set of bits are activated to be read or written with the second clock gating signal when data from a corresponding second set of data storage locations is to have data read therefrom or written to, wherein the first set of bits is non-overlapping with the second set of bits, and wherein the first set of data storage locations is non-overlapping with the second set of data storage locations.

19. The control circuit of claim 18, wherein the first set of bits are deactivated in an absence of the first clock gating signal when data from the corresponding first set of data storage locations is not to have data read therefrom or no data to be written and wherein the second set of bits are deactivated in an absence of the second clock gating signal when data from the corresponding second set of data storage locations is not to have data read therefrom or no data to be written.

20. The control circuit of claim 17, wherein a number of bits in the array of bits is equal to a number of data storage locations in the storage element.

21. The control circuit of claim 17, wherein the array of bits of bits is divided into a number of subgroups and wherein each subgroup in the number of subgroups provided with a corresponding switching element to manage a clock gate provided to the corresponding subgroup.

22. A semiconductor device, comprising:
an array of bits indicating an availability for a corresponding data storage location in a data storage element, wherein the array of bits is divided into a number of subgroups; and
a control circuit to manage clock gating for the array of bits, wherein the control circuit provides a separate clock gating signal to each subgroup of bits in the array of bits to independently control when each subgroup is activated.

23. The semiconductor device of claim 22, wherein each subgroup, in an absence of receiving a clock-enable (CE) signal from the control circuit, is deactivated and requires less power as compared to when the subgroup is activated with a CE signal.

24. The semiconductor device of claim 22, wherein the control circuit comprises a number of switching elements equal to the number of subgroups and wherein each switching element is used to selectively control whether a clock-enable (CE) signal is provided to a corresponding subgroup.
